(19) United States
(12) Patent Application Publication
(10) Pub. No.: US 2017/0133537 A1
(43) Pub. Date: May 11, 2017

(54) INTEGRATED BACK-SHEETS FOR BACK-CONTACT SOLAR CELL MODULES

(71) Applicant: E I DU PONT DE NEMOURS AND COMPANY, Wilmington, DE (US)

(72) Inventors: Zelin Liu, Shanghai (CN); Peng Li, Shanghai (CN)

(21) Appl. No.: 15/127,466

(22) PCT Filed: Mar. 21, 2014
(86) PCT No.: PCT/CN14/73811

§ 371 Date: Sep. 20, 2016

(51) Int. Cl. H01L 31/05; H01L 31/049

(52) U.S. Cl. CPC H01L 31/0516; H01L 31/049

(57) ABSTRACT

Disclosed herein is an integrated back-sheet for a back-contact solar cell module, which comprises: (i) a polymeric substrate having a back surface and a front surface; (ii) a tie layer comprising a back sub-layer and a front sub-layer, in which the back sub-layer is adhered to the front surface of the polymeric substrate, and in which the back sub-layer is comprised of one or more ethylene copolymers and the front sub-layer is comprised of a blend of one or more ethylene copolymers and one or more polyolefins at a weight ratio of about 3:97-60:40 or about 5:95-55:45; and (iii) electrically conductive metal circuits adhered to the front sub-layer of the tie layer. Also disclosed herein are processes for forming such an integrated back-sheet, back-contact solar cell modules made with such an integrated back-sheet, and processes for forming such back-contact solar cell modules

### FIELD OF THE INVENTION

The present invention relates to integrated back-sheets for back-contact solar cell modules and back-contact solar cell modules comprising the integrated back-sheets.

### BACKGROUND

Solar cells (or photovoltaic cells) convert radiant energy, such as sunlight, into electrical energy. In practice, multiple solar cells are electrically connected together in series or in parallel and are protected within a solar module (or photovoltaic module).

Solar cells typically have electrical contacts on both the front and back sides of the solar cells. However, contacts on the front sunlight receiving side of the solar cells can cause up to a 10% shading loss. In back-contact solar cells, all of the electrical contacts are moved to the back side of the solar cells. With both the positive and negative polarity electrical contacts on the back side of the solar cell, electrical circuitry is needed to provide electrical connections to the positive and negative polarity electrical contacts on the back of the solar cell.

PCT Patent Application Publication No. WO2013063738 discloses a method for preparing integrated back-sheets for back-contact solar cell modules, which involves a die cut process. For example, the method includes: adhering a conductive metal foil to a polymer substrate; die cutting the conductive metal foil to separate the metal foil into two or more conductive metal foil sections; and removing the parts of the metal foil that separate the conductive metal foil sections to form one or more patterned metal foil circuits from the remaining metal foil. In order to provide sufficient bonding between the polymer substrate and the conductive metal foil, an ethylene copolymer adhesive layer maybe extruded therebetween. However, it is found that the bonding strength between the ethylene copolymer adhesive layer and the metal foil is greater than the bonding strength between the ethylene copolymer adhesive layer and the polymer substrate. Consequently, after die cutting and when the parts of the metal foil that separate the conductive metal foil sections are removed, the ethylene copolymer adhesive layer positioned underneath these parts also may be removed, and the polymer substrate positioned underneath the ethylene copolymer adhesive layer may be damaged. Thus, there is still a need to develop a novel formulation for the adhesive layer extruded between the conductive metal foil and the polymer substrate to solve such problems.

### SUMMARY

Provided herein is an integrated back-sheet for a back-contact solar cell module, which comprises: a) a polymeric substrate having a back surface and a front surface, wherein, the front surface faces towards a light source when in use; b) a tie layer comprising a back sub-layer and a front sub-layer, wherein, the back sub-layer is adhered to the front surface of the polymeric substrate, and wherein, the back sub-layer is comprised of one or more ethylene copolymers and the front sub-layer is comprised of a blend of one or more ethylene copolymers and one or more polyolefins at a weight ratio of about 3:97-60:40; and c) electrically conductive metal circuits adhered to the front sub-layer of the tie layer.

In one embodiment of the integrated back-sheet, the ethylene copolymers are selected from the group consisting of ethylene/alkyl (meth)acrylate copolymers, ethylene/alkyl (meth)acrylic acid copolymers, ionomers derived from ethylene/(meth)acrylic acid copolymers, and combinations of two or more thereof, or, the ethylene copolymers are selected from the group consisting of ethylene/acrylate copolymer, ethylene/methyl acrylate copolymer, ethylene/acrylic acid copolymer, ethylene/methacrylic acid copolymer, ionomers derived from ethylene/acrylic acid copolymers or ethylene/methacrylic acid copolymers, and combinations of two or more thereof.

In a further embodiment of the integrated back-sheet, the polyolefins are selected from the group consisting of homopolymers of an olefin and copolymers of two or more distinct olefins, or, the polyolefins are selected from the group consisting of linear or branched poly-α-olefins and cyclic polyolefins, or, the polyolefins are selected from the group consisting of high density polyethylenes (HDPE), polypropylenes (PP), low density polyethylenes (LDPE), linear low density polyethylenes (LLDPE), and combinations of two or more thereof.

In a yet further embodiment of the integrated back-sheet, the polymeric substrate is comprised of one or more polymeric materials selected from the group consisting of polyester, fluoropolymer, polycarbonate, polypropylene, polyethylene, cyclic polyolefin, acrylic, cellulose acetate, acrylate polymer, polystyrene, styrene-acrylate copolymers, acrylonitrile-styrene copolymers, poly(ethylene naphthalate), polyethersulfone, polysulfone, polyamide, epoxy resin, glass fiber reinforced polymer, carbon fiber reinforced polymer, vinyl chloride polymers, polyvinylidene chloride, vinylidene chloride copolymers, and combinations of two or more thereof, or, the polymeric substrate is comprised of one or more polymeric materials selected from the group consisting of polyesters, fluoropolymers.

In a yet further embodiment of the integrated back-sheet, the polymeric substrate is in form of a mono-layer sheet or film or in the form of a multi-layer sheet or film.

In a yet further embodiment of the integrated back-sheet, the electrically conductive metal circuits are formed from a metal foil, or the electrically conductive metal circuits are formed of a foil of aluminum, tin, copper, nickel, silver, gold, tin coated copper, silver coated copper, gold coated copper, steel, invar, or alloys of two or more thereof, or, the electrically conductive metal circuits are formed of an aluminum foil.

Further provided herein is a back-contact solar cell module, comprising: a) the integrated back-sheet provided above; b) an insulating layer adhered to the electrically conductive metal circuits of the integrated back-sheet, wherein the insulating layer comprises a plurality of openings that are filled with electrically conductive material; c) a plurality of back-contact solar cells having a light receiving side and an opposite back side, wherein, the back contact solar cells each have a plurality of electrical contacts on their back side in a pattern corresponding to the pattern of openings in the insulating layer that are filled with electrically conductive material, and wherein, the back side of the plurality of back-contact solar cells are adhered to the insulating layer such that the electrical contacts on the back side of the solar cells are in electrical contact with the electrically conductive metal circuit through the electrically conductive material in the openings in the insulating layer; d) a front encapsulant layer adhered to the front side of the back-contact solar cells; and e) a transparent front-sheet adhered to the front encapsulant layer.

### BRIEF DESCRIPTION OF THE DRAWINGS

The detailed description will refer to the following drawings which are not drawn to scale and wherein like numerals refer to like elements:

FIG. 1 is a schematic illustration of a method for forming the integrated back-sheet disclosed herein.

FIG. 2 is a cross-sectional view of a back-contact solar cell module disclosed herein.

### DETAILED DESCRIPTION OF THE INVENTION

Disclosed herein is an integrated back-sheet for a back-contact solar cell module, processes for preparing such an integrated back-sheet, back-contact solar cell modules made with such an integrated back-sheet, and processes for preparing such back-contact solar cell modules.

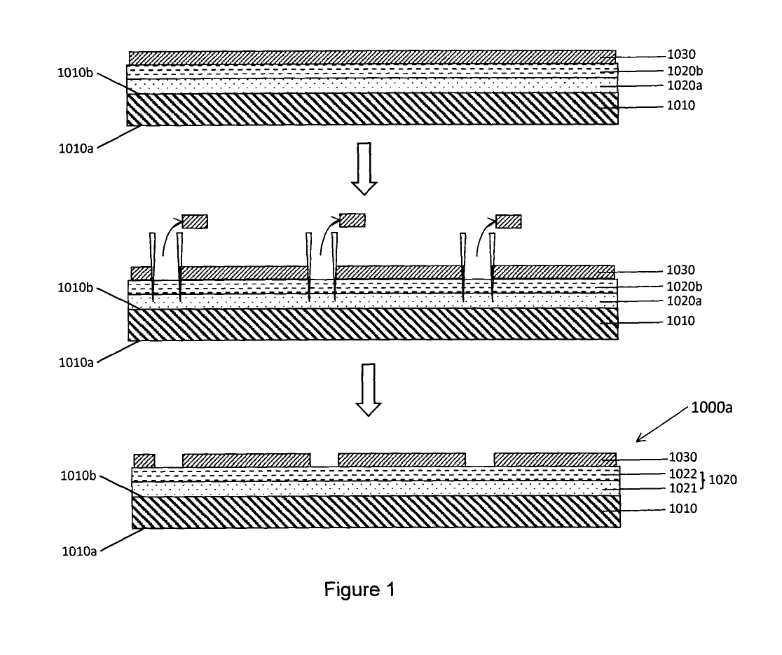

As shown in FIG. 1, the disclosed integrated back-sheet (1000a) comprises:
(i) a polymeric substrate (1010) having a back surface (1010a) and a front surface (1010b) (wherein, the front surface faces towards the light source when in use);
(ii) a tie layer (1020) comprising a back sub-layer (1021) and a front sub-layer (1022), in which the back sub-layer (1021) is adhered to the front surface of the polymeric substrate (1010b), and in which the back sub-layer (1021) is comprised of one or more ethylene copolymers and the front sub-layer (1022) is comprised of a blend of one or more ethylene copolymers and one or more polyolefins at a weight ratio of about 3:97-60:40 or about 5:95-55:45; and
(iii) electrically conductive metal circuits (1030) adhered to the front sub-layer of the tie layer (1022).

And in the disclosed integrated back-sheet, the bonding strength between the back sub-layer of the tie layer (1021) and the polymeric substrate (1010) is stronger than the bonding strength between the front sub-layer of the tie layer (1022) and the metal circuit (1030).

The polymeric substrate (1010) used herein is comprised of polymeric materials, optionally in conjunction with other materials, used in photovoltaic back-sheets. Exemplary polymeric materials useful herein include, without limitation, polyester, fluoropolymer, polycarbonate, polypropylene, polyethylene, cyclic polyolefin, acrylic, cellulose acetate, acrylate polymer such as polymethylmethacrylate (PMMA), polystyrene, styrene-acrylate copolymers, acrylonitrile-styrene copolymers, poly(ethylene naphthalate), polyethersulfone, polysulfone, polyamide, epoxy resin, glass fiber reinforced polymer, carbon fiber reinforced polymer, vinyl chloride polymers, polyvinylidene chloride, vinylidene chloride copolymers, and combinations of two or more thereof. Preferably, the polymeric materials used in the polymeric substrate (1010) are selected from polyesters and fluoropolymers. Suitable polyesters include polyethylene terephthalate (PET), polytrimethylene terephthalate (PTT), polybutylene terephthalate (PBT), polyhexamethylene terephthalate, polyethylene phthalate, polytrimethylene phthalate, polybutylene phthalate, polyhexamethylene phthalate or a copolymer or blend of two or more of the above. Suitable fluoropolymers include polyvinylfluoride (PVF), polyvinylidene fluoride, polytetrafluoroethylene, ethylene-tetrafluoroethylene copolymers and combinations thereof.

The polymeric substrate (1010) may be in the form of a mono-layer sheet or film, and the mono-layer sheet or film is comprised of any suitable polymeric materials described above.

Or, the polymeric substrate (1010) may be in the form of a multi-layer sheet or film. In such embodiments, the multi-layer polymeric substrate is formed of two or more sub-layers that are adhered together with or without adhesives. Also, the multi-layer polymeric substrate (1010) may comprise one or more non-polymeric sub-layers, provided that at least the sub-layer that is positioned to the front surface of the polymeric substrate and adhered to the back sub-layer of the tie layer (1021) is comprised of polymeric materials. Suitable materials that may be used in forming the non-polymeric sub-layers include, without limitation, metallic materials (such as aluminum foil, aluminum panel, copper, steel, alloy, stainless steel, etc.), non-metallic inorganic materials (such as amorphous materials (e.g., glass) and crystalline materials (e.g., quartz)), inorganic compounds, ceramics, and minerals (such as mica or asbestos). Moreover, the multi-layer polymeric substrate (1010) may further comprise one or more non-polymeric coatings applied over one or more of the sub-layers, provided that at least the sub-layer that is positioned to the front surface of the polymeric substrate (1010b) and adhered to the back sub-layer of the tie layer (1021) is comprised of polymeric materials and the front surface thereof is free of any non-polymeric coating. The non-polymeric coatings may be metallic, metal oxide or non-metal oxide surface coating. Such coatings are helpful for reducing moisture vapor transmission through the integrated back-sheet structure. The thickness of such a metallic, metal oxide layer or non-metal oxide layer on one or more of the polymer films typically measures between 50 Å and 4000 Å, and more typically between 100 Å and 1000 Å, but may be up to 50 um thick.

There are no specific restrictions on the thickness of the polymeric substrate (1010) or on the thickness of the various sub-layers of the polymeric substrate (1010). Thickness varies according to specific application. In one preferred embodiment, the polymeric substrate (1010) comprises a fluoropolymer (e.g., PVF) layer with a thickness in the range of 10-50 μm and adhered to a polyester (e.g., PET) film with a thickness of 50-500 μm.

Various known additives and fillers may be added to the various layer(s) of the polymeric substrate (1010) to satisfy various different requirements. Suitable additives may include, without limitation, light stabilizers, UV stabilizers and absorbers, thermal stabilizers, anti-hydrolytic agents, light reflection agents, flame retardants, pigments, titanium dioxide, dyes, slip agents, calcium carbonate, silica, and reinforcement additives such as glass fibers and the like. There are no specific restrictions to the content of the additives and fillers in the polymeric substrate layer(s) as long as the additives do not produce an undue adverse impact on the polymeric substrate layer(s) or their adhesion to other layer(s) of the integrated back-sheet.

In one embodiment, the polymeric substrate (1010) is in the form of a mono-layer film or sheet and it is formed of materials selected from polyesters, fluoropolymers, and blends of two or more thereof.

In a further embodiment, the polymeric substrate (1010) is in the form of a multi-layer film or sheet and it is formed of a laminate of polyester film(s) and fluoropolymer film(s). For example, the polymeric substrate may comprise a polyester film (e.g., a bi-axially oriented PET film) adhered to a fluoropolymer film (e.g., a PVF film). In such an embodiment, it is preferred that the polyester film layer is positioned to the front surface of the polymeric substrate (1010b). Or, the polymeric substrate may comprise a polyester film (e.g., a bi-axially oriented PET film) with two fluoropolymer films (e.g., two PVT films) adhered to the opposite sides thereof.

In accordance with the present disclosure, the tie layer (1020) comprises a back sub-layer (1021) and a front sub-layer (1022). The back sub-layer (1021) is formed of a polymeric composition consisting essentially of one or more ethylene copolymers, the front sub-layer (1022) is formed of a polymeric composition consisting essentially of a blend of one or more ethylene copolymers and one or more polyolefins at a weight ratio of about 3:97-60:40 or about 5:95-55:45, and the bonding strength between the polymeric substrate (1010) and the back sub-layer (1021) is greater than the bonding strength between the front sub-layer (1022) and the electrically conductive metal circuit (1030).

The ethylene copolymers used herein are E/X copolymers wherein E is an α-olefin (or preferably, ethylene), X is selected from C₃ to C₈ unsaturated monocarboxylic acids or dicarboxylic acids (or acid anhydrides thereof), metal salts of the C₃ to C₈ unsaturated monocarboxylic acids or dicarboxylic acids (i.e., the C₃ to C₈ unsaturated monocarboxylic acids or dicarboxylic acids that are partially or completely neutralized by metal ions), and alkyl esters of the C₃ to C₈ unsaturated monocarboxylic acids or dicarboxylic acids in which the alkyl groups have from 1 to 8 carbon atoms.

Illustrative examples of unsaturated monocarboxylic acids used as X include acrylic acid and methacrylic acid. Illustrative examples of unsaturated dicarboxylic acids used as X include maleic acid, fumaric acid and itaconic acid. Illustrative examples of unsaturated carboxylic acid anhydrides used as X include maleic anhydride and itaconic anhydride. The use of maleic acid and maleic anhydride is especially preferred.

Illustrative examples of the alkyl esters of the above unsaturated monocarboxylic acids which are suitable for use as X include, without limitation, methyl methacrylate, ethyl methacrylate, propyl methacrylate, butyl methacrylate, methyl acrylate, ethyl acrylate, propyl acrylate and butyl acrylate. Illustrative examples of the half esters of the above dicarboxylic acids include, without limitation, monoesters of the above-mentioned dicarboxylic acids, such as monoethyl maleate, monomethyl fumarate, and monoethyl itaconate.

The metal ions used herein in the metal salts of the above unsaturated carboxylic acids may be monovalent, divalent, trivalent or multivalent. Combinations of two or more metal ions having different valencies, for example mixtures of Na⁺ and Zn²⁺, are also suitable. Suitable monovalent metal ions include, without limitation, ions of sodium, potassium, lithium, silver, mercury, copper, and the like, and mixtures of two or more thereof. Suitable divalent metal ions include, without limitation, ions of beryllium, magnesium, calcium, strontium, barium, copper, cadmium, mercury, tin, lead, iron, cobalt, nickel, zinc, and the like, and mixtures of two or more thereof. Suitable trivalent metal ions include, without limitation, ions of aluminum, scandium, iron, yttrium, and the like, and mixtures of two or more thereof. Suitable multivalent metal ions include, without limitation, zirconium, hafnium, vanadium, tantalum, tungsten, chromium, cerium, iron, and the like, and mixtures of two or more thereof. It is noted that when the metal ion is multivalent, complexing agents such as stearate, oleate, salicylate, and phenolate radicals may be included, as described in U.S. Pat. No. 3,404,134. The metal ions are preferably monovalent or divalent ions. More preferably, the metal ions are selected from the group consisting of ions of sodium, lithium, magnesium, zinc, potassium, and mixtures of two or more thereof. Yet more preferably, the metal ions are selected from the group consisting of ions of sodium, zinc, and mixtures thereof. Still more preferably, the metal ions comprise or consist essentially of zinc ions.

Moreover, the E/X copolymers used herein may optionally further comprise other suitable additional comonomers, such as unsaturated carboxylic acids having 2 to 10, or preferably 3 to 8 carbons, or derivatives thereof. Suitable acid derivatives include acid anhydrides, amides, and esters. Esters are preferred. Specific examples of preferred esters of unsaturated carboxylic acids include, but are not limited to, methyl acrylates, methyl methacrylates, ethyl acrylates, ethyl methacrylates, propyl acrylates, propyl methacrylates, isopropyl acrylates, isopropyl methacrylates, butyl acrylates, butyl methacrylates, isobutyl acrylates, isobutyl methacrylates, tert-butyl acrylates, tert-butyl methacrylates, octyl acrylates, octyl methacrylates, undecyl acrylates, undecyl methacrylates, octadecyl acrylates, octadecyl methacrylates, dodecyl acrylates, dodecyl methacrylates, 2-ethylhexyl acrylates, 2-ethylhexyl methacrylates, isobornyl acrylates, isobornyl methacrylates, lauryl acrylates, lauryl methacrylates, 2-hydroxyethyl acrylates, 2-hydroxyethyl methacrylates, glycidyl acrylates, glycidyl methacrylates, poly(ethylene glycol)acrylates, poly(ethylene glycol)methacrylates, poly(ethylene glycol) methyl ether acrylates, poly(ethylene glycol) methyl ether methacrylates, poly(ethylene glycol) behenyl ether acrylates, poly(ethylene glycol) behenyl ether methacrylates, poly(ethylene glycol) 4-nonylphenyl ether acrylates, poly(ethylene glycol) 4-nonylphenyl ether methacrylates, poly(ethylene glycol) phenyl ether acrylates, poly(ethylene glycol) phenyl ether methacrylates, vinyl acetates, vinyl propionates, and combinations of two or more thereof. Examples of preferred comonomers include, but are not limited to, methyl (meth)acrylates, butyl (meth)acrylates, vinyl acetates, and combinations of two or more thereof.

In accordance with the present disclosure, the E/X copolymer used herein comprises about 5-40 wt %, or about 10-35 wt %, or about 10-30 wt % of copolymerized units of X. The remainder of the E/X copolymer comprises copolymerized units of the α-olefin (e.g., ethylene) and up to about 5 wt % of copolymerized units of the optional additional comonomers, if any. These weight percentages are based on the total weight of E/X copolymer.

In embodiments wherein the E/X copolymer is an ionomer, the neutralization levels are about 10-90%, or about 20-60%, or about 15-30%. Neutralization level is expressed as the weight percentage of the unsaturated carboxylic acid present in the E/X copolymer that is neutralized. For example, if the E/X copolymer contains 15 wt % of methacrylic acid and the neutralization level is 25%, then 3.75 wt % of the acid groups are neutralized, based on the total weight of the copolymer.

The ethylene copolymers used herein may be selected from ethylene/alkyl (meth)acrylate copolymers, ethylene/alkyl (meth)acrylic acid copolymers, ionomers (i.e., ethylene/(meth)acrylic acid copolymers that are partially or completely neutralized with metal ions), and combinations of two or more thereof. Exemplary ethylene copolymers include, without limitation, ethylene/acrylate copolymer, ethylene/methyl acrylate copolymer, ethylene/acrylic acid copolymer, and ethylene/methacrylic acid copolymer. Exemplary ethylene copolymers also include ionomers derived from ethylene/acrylic acid copolymers or ethylene/methacrylic acid copolymers, such as ionomers derived from ethylene/methacrylic acid copolymers, which are partially neutralized by zinc ion, or ionomers derived from ethylene/methacrylic acid copolymers, which are partially neutralized by sodium ion.

The ethylene copolymers used herein also are commercially available. Examples include those available from E. I. du Pont de Nemours and Company, Wilmington, Del. (“DuPont”) under the trade names Bynel®22E757, Nucrel® 0910, Surlyn® 1702, Surlyn® 8945, Elvaloy®AC 1609, and Fusabond®.

The polyolefins used herein include homopolymers of an olefin or copolymers of an olefin and another olefin. The polyolefins used herein include, without limitation, linear or branched poly-α-olefins and cyclic polyolefins. Illustrative examples of linear poly-α-olefins include high density polyethylene (HDPE) and polypropylene (PP). Illustrative examples of branched poly-α-olefin homopolymers include low density polyethylene (LDPE). Illustrative examples of branched poly-α-olefin copolymers include linear low density polyethylene (LLDPE).

The polyolefins used herein also are commercially available, such as, LLDPE from Hanwha Chemical (Korea) or LDPE from LyondellBasell (U.S.A.).

The tie layer (1020) may further comprise other sub-layers or adhesives bonded between the back sub-layer (1021) and the front sub-layer (1022). Also, the sub-layers of the tie layer (1020) may be bonded together by any suitable process, such as, lamination, co-extrusion, vacuum lamination, extrusion lamination, hot press, etc. Preferably, the sub-layers of the tie layer are bonded together by co-extrusion. There are no specific restrictions on the thickness of the tie layer (1020) or on the thickness of the various sub-layers of the tie layer (1020). Thickness varies according to specific application. In one preferred embodiment, the tie layer (1020) may have a total thickness ranging from about 5-2000 μm, while the back sub-layer (1021) may have a thickness ranging from about 2-1000 μm, and the front sub-layer (1022) may have a thickness ranging from about 2-1000 μm.

The electrically conductive metal circuits (1030) may be formed from a metal foil, the foil is preferably an electrically conductive metal foil such as foil of aluminum, tin, copper, nickel, silver, gold, tin coated copper, silver coated copper, gold coated copper, steel, invar, and alloys thereof. Aluminum foil and copper foil are most commonly selected on the basis of cost and other factors. The thickness of the foil may be in the range of about 5-200 μm, or preferably 10-150 μm. In accordance with the present disclosure, the electrically conductive metal circuits (1030) are formed from a metal foil adhered to the tie layer (1020) and etched, die-cut or otherwise formed into one or more patterned electrically conductive circuits. Preferably, the electrically conductive metal circuits (1030) are formed from a metal foil adhered to the tie layer (1020) and die-cut into one or more patterned electrically conductive circuits.

The process for forming the disclosed integrated back-sheet (1000a) includes: providing a laminated structure comprising, from back to front, the polymeric substrate layer (1010), the tie layer (1020), and an electrically conductive metal foil, in which the back sub-layer (1021) is adhered to the polymeric substrate layer (1010) and the front sub-layer of the tie layer (1022) is adhered to the metal foil; die-cutting the metal foil to separate the metal foil into two or more conductive metal foil sections; removing the parts of the metal foil that separates the two or more of conductive metal foil sections to form the patterned electrically conductive metal circuits (1030) from the remaining conductive metal foil sections. During the die-cutting process, the blades may cut into portions of the tie layer (1020). However, because the bonding strength between the back sub-layer of the tie layer (1021) and the polymeric substrate is greater than the bonding strength between the front sub-layer of the tie layer (1022) and the metal foil, when the parts of the metal foil that separates the two or more of conductive metal foil sections are removed, the sections of the tie layer (1022) underneath these removed parts of the metal foil will remain adhered to the polymeric substrate (1010). As the tie layer (1020) remains intact after the die-cutting process, it provides protection to the polymeric substrate (1010). Also, when the integrated back-sheet (1000a) is laminated into a back-contact solar cell module (1000, as disclosed below), parts of the tie layer (1020) have direct contact with the insulating layer (1040) through the cracks of the electrically conductive metal circuits (1030) and therefore can form strong bonding to the insulating layer. Moreover, when the integrated back-sheet (1000a) is laminated into a back-contact solar cell module (1000, as disclosed below), the back-contact solar cells (1050) often has a smaller surface area than the tie layer (1020, which is positioned below the solar cells (1050)) and the front encapsulant layer (1060, which is positioned above the solar cells (1050)), therefore, the tie layer (1020) also can form strong bonding with the front encapsulant layer (1060) at the area surrounding the edges of the back-contact solar cells (1050).

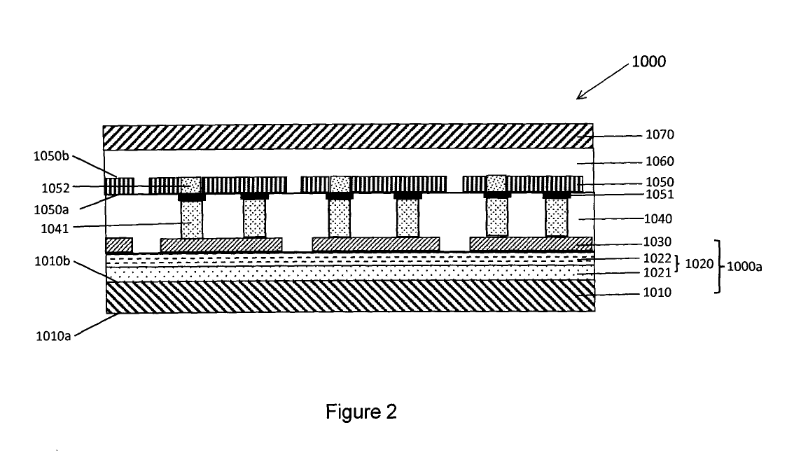

As shown in FIG. 2, the disclosed back-contact solar cell module (1000) made with the as such disclosed integrated back-sheet (1000a) comprises:
(i) the integrated back-sheet (1000a);
(ii) an insulating layer (1040) adhered to the electrically conductive metal circuits (1030), wherein the insulating layer comprises a plurality of openings (1041) that are filled with electrically conductive material;
(iii) a plurality of back-contact solar cells (1050) having a light receiving side (1050b) and an opposite back side (1050a), wherein, the back contact solar cells each have a plurality of electrical contacts (1051) on their back side in a pattern corresponding to the pattern of openings in the insulating layer (1041) that are filled with electrically conductive material, and wherein, the back side of the plurality of back-contact solar cells (1050a) are adhered to the insulating layer (1040) such that the electrical contacts on the back side of the solar cells (1051) are in electrical contact with the electrically conductive metal circuit (1030) through the electrically conductive material in the openings in the insulating layer (1041);
(iv) a front encapsulant layer (1060) adhered to the front side of the back-contact solar cells (1050b); and
(v) a transparent front-sheet (1070) adhered to the front encapsulant layer (1060).

The insulating layer (1040) may comprise suitable inorganic materials, organic materials, or combinations of inorganic and organic materials. Suitable inorganic materials that may be comprised in the insulating layer (1040) include, without limitation, non-metallic inorganic materials (such as amorphous materials (e.g., glass) or crystalline materials (e.g., quartz)), inorganic compounds, ceramics, and minerals (such as mica or asbestos). Preferably, the insulating layer (1040) includes at least one polymeric layer that will adhere to the electrically conductive metal circuit (1030) and to the back side of the back-contact solar cell (1050a). Also, the insulating layer (1040) may be in the form of a mono-layer polymeric film, or in the form of a multi-layer polymeric film.

The insulating layer (1040) may, for example, be an extruded polymer layer that is extruded over the electrically conductive metal circuits (1030) and compressed against the electrically conductive metal circuits (1030) using a compression roller or press. Alternatively, the insulating layer (1040) may be applied as a film and thermally pressed against the electrically conductive metal circuits (1030) and the underlying tie layer (1020) and polymeric substrate (1010) using a roller or press. The insulating layer (1040) preferably has a thickness in the range of about 5-2000 μm and more preferably within the range of about 10-500 μm. The insulating layer (1040) may be comprised of a polymer with adhesive properties that allow it to adhere directly to the electrically conductive metal circuits (1030), or another adhesive, such as a polyurethane adhesive, may be applied between the insulating layer (1040) and the electrically conductive metal circuits (1030). The insulating layer (1040) preferably includes at least one layer of polymer that remains very viscous at typical photovoltaic module lamination temperatures of about 120-180° C., and more preferably about 125-160° C.

Suitable polymeric materials that could be comprised in the insulating layer (1040) include, without limitation, ethylene copolymers, polyolefins, poly(vinyl butyral) (PVB), polyurethane (PU), polyvinylchloride (PVC), acid copolymers, silicone elastomers, epoxy resins, or a combination thereof. Suitable ethylene copolymers include, without limitation, ethylene vinyl acetates (EVA), ethylene acrylate copolymers (such as poly(ethylene-co-methyl acrylate) and poly(ethylene-co-butyl acrylate)), ionomers, and the like. Exemplary PVB based materials include, without limitation, DuPont™ PV5200 series encapsulant sheets. Exemplary ionomer based materials include, without limitation, DuPont™ PV5300 series encapsulant sheets and DuPont™ PV5400 series encapsulant sheets from DuPont. Another exemplary polyolefin for the polymeric layer is metallocene-catalyzed linear low density polyethylenes. The insulating layer may include cross-linking agent that promotes cross-linking upon heating so that the polymer layer remains very viscous throughout the thermal lamination of the module.

The insulating layer may be comprised of an extruded or cast thermoplastic polymer layer. Thermoplastic ethylene copolymers that can be utilized for the insulating layer include the ethylene copolymers disclosed in PCT Patent Publication No. WO2011/044417. Preferred ethylene copolymers are comprised of ethylene and one or more monomers selected from the group of consisting of C₁₋₄ alkyl acrylates, 4 alkyl methacrylates, methacrylic acid, acrylic acid, glycidyl methacrylate, maleic anhydride and copolymerized units of ethylene and a comonomer selected from the group consisting of C₄-C₈ unsaturated anhydrides, monoesters of C₄-C₈ unsaturated acids having at least two carboxylic acid groups, diesters of C₄-C₈ unsaturated acids having at least two carboxylic acid groups and mixtures of such copolymers, wherein the ethylene content in the ethylene copolymer preferably accounts for 60-90% by weight.

The insulating layer (1040) may further contain any additive(s) and/or filler(s) known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, anti-hydrolytic agents, light reflection agents, pigments, titanium dioxide, dyes, slip agents, calcium carbonate, dispersants, surfactants, chelating agents, coupling agents, adhesives, primers, reinforcement additives, such as glass fiber, fillers and the like. There are no specific restrictions on the content of the additives and fillers in the insulating layer (1040) as long as the additives do not produce an undue adverse impact on the insulating layer (1040) or its adhesion to the electrically conductive metal circuits (1030) or the back-contact solar cells (1050).

In addition, vias or openings (1041) are formed in the insulating layer (1040) to enable electrical connection between the electrical contacts on the back of the solar cells (1051) and the electrically conductive metal circuit (1030). These vias or openings (1041) are filled with an electrically conductive material that provides electrical connection through the openings and between the electrical contacts on the back of the solar cells (1051) and the electrically conductive metal circuit (1030). The electrically conductive material that are used to fill the vias or openings of the insulation layer (1041) may be solid blanks of an electrically conductive material that are inserted into the openings, may be a conductive liquid or molten material, or may be a conductive powder that will solidify and adhere to the electrically conductive metal circuit (1030) and to the electrical contacts of a back-contact solar cell (1051) during module lamination. Electrically conductive solid material that can be used herein may be conductive polymers such as polyacetylene and polyphenylene vinylene. The electrically conductive solid material used herein also may be electrically conductive adhesives comprised of polymer base matrix and conductive fillers. The polymer base matrix can, for example, be ethylene copolymer, polyimide, acrylate, silicone elastomer, or fluoroelastomer. The conductive fillers can be metal particles such as Ag, Cu, Ni, W, metal coated particles such as Ag-coated polystyrene powder, Au-coated glass beads and non-metal particles such as carbon nanotubes or graphene. For example, suitable electrically conductive adhesives include ethylene/vinyl acetate copolymer loaded with a conductive metal powder or flakes such as silver powder, or ethylene/acrylic elastomer loaded with silver powders. The electrically conductive adhesives that may be used is an adhesive that is thermally cured for dimensional stability during normal vacuum thermal lamination of PV module, and may be a conductive adhesive such as Loctite 3888 or Loctite 5421 from Henkel Corporation, of Germany. An electrically conductive powder that can be used to form the electrically conductive material is a conductive powder that can be sintered by heat treatment. Examples include Sn42/Bi58 low temperature alloy particles, nano-Ag particles, and low temperature alloy coated polystyrene particles.

The disclosed back-contact solar cell module comprises one or more back-contact solar cells (1050) aligned over the insulating layer (1040). Back-contact solar cells (1050), as can be seen in FIG. 2, have both positive and negative polarity back side electrical contacts (1051). The back contacts (1051) that can be seen in the cross-sectional view of FIG. 2 connect to the front side of the solar cell through electrically conductive paste in vias (1052) in the solar cell (1050). Other back contacts (1051) in FIG. 2 electrically connect to the back side of the solar cell (1050). The back contacts (1051) on the back side of the solar cell align with the openings (1041) that have been formed in the insulating layer (1040) when the solar cells (1050) are placed over the insulating layer (1040).

In the disclosed back-contact solar cell module, a front encapsulant layer (1060) is arranged over the front side of the solar cells (1050) and a transparent front-sheet (1070), such as a glass or polymer front sheet, is placed over the front encapsulant layer (1060). A typical glass type front-sheet (1070) is 3.2 mm thick annealed low iron glass. The front encapsulant layer (1060) may be comprised of any of the polymers described here above with regard to the insulating layer. The front encapsulant layer (1060) may include cross-linking agent that promotes cross-linking upon heating so that the polymer layer remains viscous throughout the thermal lamination of the module.

The disclosed back-contact solar cell module (1000) may be prepared by any suitable lamination process. For example, the process may include:
a) laying up all the component layers (as shown in FIG. 2) to form a pre-lamination assembly;
b) laminating the pre-lamination assembly into the disclosed back-contact photovoltaic module by applying heat and pressure to the pre-lamination assembly.

The lamination process used herein may be an autoclave or non-autoclave processes. For example, the pre-lamination assembly described above may be laid up in a vacuum lamination press and laminated together under vacuum with heat and standard atmospheric or elevated pressure. The pre-lamination assembly is laminated under heat and pressure and a vacuum (for example, in the range of about 27-28 inches (689-711 mm) Hg) to remove air. In an exemplary procedure, the pre-laminated assembly is placed into a bag capable of sustaining a vacuum (“a vacuum bag”), the air is drawn out of the bag using a vacuum line or other means of pulling a vacuum on the bag, the bag is sealed while maintaining the vacuum, the sealed bag is placed in an autoclave at a temperature of about 120-180° C., at a pressure of about 200 psi (about 15 bars), for about 10-50 minutes. Preferably the bag is autoclaved at a temperature of about 120-160° C. for about 10-45 minutes. More preferably the bag is autoclaved at a temperature of about 135-160° C. for about 10-40 minutes.

Air trapped within the pre-lamination assembly may be removed through a nip roll process. For example, the pre-lamination assembly may be heated in an oven at a temperature of about 80-120° C., or preferably, at a temperature of about 90-100° C., for about 30 minutes. Thereafter, the heated assembly may be passed through a set of nip rolls so that the air in the void spaces between the component layers may be squeezed out, and the edge of the assembly sealed. This process may provide the final back-contact solar cell module (1000) or may provide what is referred to as a pre-press assembly, depending on the materials of construction and the exact conditions utilized.

The pre-press assembly may then be placed in an air autoclave where the temperature is raised to about 120-160° C., or preferably, about 135-160° C., and the pressure is raised to about 100-300 psig, or preferably, about 200 psig (14.3 bar). These conditions are maintained for about 10-60 minutes, or preferably, about 10-50 minutes, after which, the air is cooled while no more air is added to the autoclave. After about 20 minutes of cooling, the excess air pressure is vented and the photovoltaic module is removed from the autoclave. The described lamination process should not be considered limiting. Essentially, any photovoltaic module lamination process known within the art may be used to produce the back-contact solar cell modules (1000) with the integrated back-sheet (1000a) as disclosed herein.

### Examples

The following Examples are intended to be illustrative of the present invention, and are not intended in any way to limit the scope of the present invention.

### Materials Used in Examples

Cu Foil: Copper foil (35 μm thick) obtained from Suzhou Fukuda Metal Co., Ltd (China);
PET Film: a corona treated (both sides) polyethylene terephthalate film (250 μm thick) obtained from DuPont Teijin Films (Japan);
PVF Film: an oriented polyvinyl fluoride film (37 μm thick) obtained from DuPont under the trade name Tedlar®;
ECP-1: ethylene/methyl acrylate copolymer obtained from DuPont under the trade name Bynel®22E757;
ECP-2: ethylene/methacrylic acid copolymer obtained from DuPont under the trade name Nucrel® 0910;
ECP-3: zinc ionomer obtained from DuPont under the trade name Surlyn® 1702;
PE: linear low density polyethylene having a density of 0.924 g/cm³, a MFI of 25 g/10 min, and melting point of 124° C.;

### Comparative Examples CE1-CE2 and Examples E1-E3

In each of CE1-CE2 and E1-E3, using a twin-screw extrusion-lamination line by Davis Standards, a layer of the Cu Foil and a layer of the PET Film were extrusion laminated two each side of a bi-layer Tie Layer. The bi-layer Tie Layer is formed of a Back Sub-layer that is directly bonded to the PET Film and a Front Sub-layer that is directly bonded to the Cu Foil. The resin composition used in forming the Back Sub-layer and the Front Sub-layer are disclosed in Table 1. In each example, two sets of extrusion laminates were prepared, each at an extrusion temperature of 260° C. or 290° C.

Then, following ASTM D1876, the 180° peel strength between the PET Film and the Tie Layer (PET/Tie) and the peel strength between the Tie Layer and the Cu Foil (Cu/Tie) were measured and recorded in Table 1.

Further, the extrusion laminate in E2 (which was prepared under the extrusion temperature of 260° C.) was subjected to vacuum lamination at 145° C. for 15 minutes, using a vacuum laminator produced by Meier Vakuumtechnik GmbH (Germany, model No. ICOLAM 10/08) and the peeling strength between Tie Layer and Cu Foil were measured in accordance with ASTM D1876 and recorded in Table 1.

TABLE 1

| | | | | |
|---|---|---|---|---|
| CE1 | E1 | E2 | E3 | CE2 |

Extrusion Laminates

| | | | | | | |
|---|---|---|---|---|---|---|
| Tie Layer | Back | ECP-1 | ECP-1 | ECP-1 | ECP-1 | ECP-1 |
| | Sub-layer | | | | | |
| | Front | PE:ECP-1 | PE:ECP-1 | PE:ECP-1 | PE:ECP-1 | PE:ECP-1 |
| | Sub-layer | (100:0) | (90:10) | (70:30) | (50:50) | (0:100) |

Extrusion temperature @ 260° C.

| | | | | | | |
|---|---|---|---|---|---|---|
| Peeling | PET/Tie | 9.9 | 10.9 | 11.1 | 10.1 | 12.3 |
| Strength | Cu/Tie | <1 | 1.6 | 2.1 | 3.9 | 15.9 |
| (N/cm) | | | | | | |

| | | | | | |
|---|---|---|---|---|---|
| Peeling Strength* (N/cm) | n/a | n/a | 14.5 | n/a | n/a |
| (After vacuum lamination) | | | | | |

Extrusion temperature @ 290° C.

| | | | | | | |
|---|---|---|---|---|---|---|
| Peeling | PET/Tie | >15 | >15 | >15 | >15 | >15 |
| Strength | Cu/Tie | 0.9 | 2.9 | 3 | 4.2 | >17 |
| (N/cm) | | | | | | |

*The Peeling strength (After vacuum lamination) was measured between the PET layer and the Cu Foil. This measurement demonstrates the bonding strength between the polymeric substrate and the electrically conductive metal circuits in the final back-contact solar cell module.

### Examples E4-E6 and Comparative Example CE3

Using a similar process used in CE1, “PET Film/bi-layer Tie Layer/Cu Foil” extrusion laminate were prepared at an extrusion temperature of 260° C. or 290° C. in each of E4-E6 and CE3. Again, the bi-layer Tie Layer is formed of a Back Sub-layer that is directly bonded to the PET Film and a Front Sub-layer that is directly bonded to the Cu Foil. The resin composition used in forming the Back Sub-layer and the Front Sub-layer are disclosed in Table 2.

Then, following ASTM D1876, the 180° peel strength between the PET Film and the Tie Layer (PET/Tie) and the peel strength between the Tie Layer and the Cu Foil (Cu/Tie) were measured and recorded in Table 2.

Further, the extrusion laminate in E5 (which was prepared under the extrusion temperature of 260° C.) was subjected to vacuum lamination at 145° C. for 15 minutes, using a vacuum laminator produced by Meier Vakuumtechnik GmbH (Germany, model No. ICOLAM 10/08) and the peeling strength between Tie Layer and Cu Foil were measured in accordance with ASTM D1876 and recorded in Table 2.

TABLE 2

| | | | |
|---|---|---|---|
| E4 | E5 | E6 | CE3 |

Extrusion Laminates

| | | | | | |
|---|---|---|---|---|---|
| Tie Layer | Back | ECP-1 | ECP-1 | ECP-1 | ECP-1 |
| | Sub-layer | | | | |
| | Front | PE:ECP-2 | PE:ECP-2 | PE:ECP-2 | PE:ECP-2 |
| | Sub-layer | (90:10) | (70:30) | (50:50) | (0:100) |

Extrusion Temperature @ 260° C.

| | | | | | |
|---|---|---|---|---|---|
| Peeling | PET/Tie | 11.5 | 10.6 | 10.5 | 13.3 |
| Strength | Cu/Tie | 2.4 | 3.7 | 5 | 18.1 |
| (N/cm) | | | | | |

| | | | | |
|---|---|---|---|---|
| Peeling Strength* | n/a | 17.1 | n/a | n/a |
| (N/cm) | | | | |
| (After vacuum | | | | |
| lamination) | | | | |

Extrusion Temperature @ 290° C.

| | | | | | |
|---|---|---|---|---|---|
| Peeling | PET/Tie | >15 | >15 | >15 | >15 |
| Strength | Cu/Tie | 2.5 | 4.1 | 5.6 | >20 |
| (N/cm) | | | | | |

*The Peeling strength (After vacuum lamination) was measured between the PET layer and the Cu Foil. This measurement demonstrates the bonding strength between the polymeric substrate and the electrically conductive metal circuits in the final back-contact solar cell module.

### Examples E7-E9 and Comparative Example CE4

Using a similar process used in CE1, “PET Film/bi-layer Tie Layer/Cu Foil” extrusion laminate were prepared at an extrusion temperature of 260° C. or 290° C. in each of E7-E9 and CE4. Again, the bi-layer Tie Layer is formed of a Back Sub-layer that is directly bonded to the PET Film and a Front Sub-layer that is directly bonded to the Cu Foil. The resin composition used in the forming the Back Sub-layer and the Front Sub-layer are disclosed in Table 3.

Then, following ASTM D1876, the 180° peel strength between the PET Film and the Tie Layer (PET/Tie) and the peel strength between the Tie Layer and the Cu Foil (Cu/Tie) were measured and recorded in Table 3.

Further, the extrusion laminate in E8 (which was prepared under the extrusion temperature of 260° C.) was subjected to vacuum lamination at 145° C. for 15 minutes, using a vacuum laminator produced by Meier Vakuumtechnik GmbH (Germany, model No. ICOLAM 10/08) and the peeling strength between Tie Layer and Cu Foil were measured in accordance with ASTM D1876 and recorded in Table 3.

TABLE 3

| | | | |
|---|---|---|---|
| E7 | E8 | E9 | CE4 |

Extrusion Laminates

| | | | | | |
|---|---|---|---|---|---|
| Tie Layer | Back | ECP-1 | ECP-1 | ECP-1 | ECP-1 |
| | Sub-layer | | | | |
| | Front | PE:ECP-3 | PE:ECP-3 | PE:ECP-3 | PE:ECP-3 |
| | Sub-layer | (90:10) | (70:30) | (50:50) | (0:100) |

Extrusion temperature @ 260° C.

| | | | | | |
|---|---|---|---|---|---|
| Peeling | PET/Tie | 10.8 | 10.6 | 12.2 | 11.3 |
| Strength | Cu/Tie | 1.5 | 2.4 | 3 | 12 |
| (N/cm) | | | | | |

| | | | | |
|---|---|---|---|---|
| Peeling Strength* | n/a | 10.2 | n/a | n/a |
| (N/cm) | | | | |
| (After vacuum | | | | |
| lamination) | | | | |

Extrusion temperature @ 290° C.

| | | | | | |
|---|---|---|---|---|---|
| Peeling | PET/Tie | >15 | >15 | >15 | >15 |
| Strength | Cu/Tie | 1.9 | 2.5 | 3.3 | >15 |
| (N/cm) | | | | | |

*The Peeling strength (After vacuum lamination) was measured between the PET layer and the Cu Foil. This measurement demonstrates the bonding strength between the polymeric substrate and the electrically conductive metal circuits in the final back-contact solar cell module.

### Examples E10-E15

Using a similar process used in CE1, “PVF Film/bi-layer Tie Layer/Cu Foil” extrusion laminate were prepared at an extrusion temperature of 260° C. in each of E10-E15. Again, the bi-layer Tie Layer is formed of a Back Sub-layer that is directly bonded to the PVF Film and a Front Sub-layer that is directly bonded to the Cu Foil. The resin composition used in forming the Back Sub-layer and the Front Sub-layer are disclosed in Table 4.

Then, following ASTM D1876, the 180° peel strength between the PVF Film and the Tie Layer (PVF/Tie) and the peel strength between the Tie Layer and the Cu Foil (Cu/Tie) were measured and recorded in Table 4.

Further, the extrusion laminate in each of E10-E15 was subjected to vacuum lamination at 145° C. for 15 minutes, using a vacuum laminator produced by Meier Vakuumtechnik GmbH (Germany, model No. ICOLAM 10/08) and the peeling strength between Tie Layer and Cu Foil were measured in accordance with ASTM D1876 and recorded in Table 4.

TABLE 4

| | | | | | |
|---|---|---|---|---|---|
| E10 | E11 | E12 | E13 | E14 | E15 |

Extrusion Laminates

| | | | | | | | |
|---|---|---|---|---|---|---|---|
| Tie Layer | Back | ECP-1 | ECP-1 | ECP-1 | ECP-1 | ECP-1 | ECP-1 |
| | Sub-layer | | | | | | |
| | Front | PE:ECP-1 | PE:ECP-1 | PE:ECP-2 | PE:ECP-2 | PE:ECP-3 | PE:ECP-3 |
| | Sub-layer | (90:10) | (70:30) | (90:10) | (70:30) | (90:10) | (70:30) |

Extrusion temperature @ 260° C.

| | | | | | | | |
|---|---|---|---|---|---|---|---|
| Peeling | PVF/Tie | 9.5 | 10.3 | 12.2 | 10.7 | 8.9 | 13 |
| Strength | Cu/Tie | 1.8 | 2.8 | 3.4 | 3.9 | 1.3 | 2.5 |
| (N/cm) | | | | | | | |

| | | | | | | |
|---|---|---|---|---|---|---|
| Peeling Strength* (N/cm) | 11.5 | >14 | 13 | 14.2 | 9.8 | 10 |
| (After vacuum lamination) | | | | | | |

*The Peeling strength (After vacuum lamination) was measured between the PVF layer and the Cu Foil. This measurement demonstrates the bonding strength between the polymeric substrate and the electrically conductive metal circuits in the final back-contact solar cell module.

As demonstrated by the above examples, when the disclosed bi-layer Tie Layer was extruded between the polymeric substrate layer (e.g., the PET film or PVF film) and the Cu Foil at either 260° C. or 290° C. (E1-E15), the peeling strength between the Tie Layer and the polymeric substrate layer was much stronger than the peeling strength between the Tie Layer and the Cu Foil. Therefore, when the Cu Foil is later subjected to die cutting, and when sections of the Cu Foil are removed away, the bi-layer Tie Layer will remain intact.

The data also demonstrates that, the disclosed bi-layer Tie Layer could provide sufficient bonding between the polymeric substrate layer and the electrically conductive metal circuits in the final back-contact solar cell module (E2, E5, E8, and E10-E15).

1. An integrated back-sheet for a back-contact solar cell module, comprising:
a) a polymeric substrate having a back surface and a front surface, wherein, the front surface faces towards a light source when in use;
b) a tie layer comprising a back sub-layer and a front sub-layer, wherein, the back sub-layer is adhered to the front surface of the polymeric substrate, and wherein, the back sub-layer is comprised of one or more ethylene copolymers and the front sub-layer is comprised of a blend of one or more ethylene copolymers and one or more polyolefins at a weight ratio of about 3:97-60:40; and
c) electrically conductive metal circuits adhered to the front sub-layer of the tie layer.

2. The integrated back-sheet of claim 1, wherein, the blend of the one or more ethylene copolymers and the one or more polyolefins are at a weight ratio of about 5:95-55:45.

3. The integrated back-sheet of claim 1, wherein, the ethylene copolymers are selected from the group consisting of ethylene/alkyl (meth)acrylate copolymers, ethylene/alkyl (meth)acrylic acid copolymers, ionomers derived from ethylene/(meth)acrylic acid copolymers, and combinations of two or more thereof.

4. The integrated back-sheet of claim 3, wherein, the ethylene copolymers are selected from the group consisting of ethylene/acrylate copolymer, ethylene/methyl acrylate copolymer, ethylene/acrylic acid copolymer, ethylene/methacrylic acid copolymer, ionomers derived from ethylene/acrylic acid copolymers or ethylene/methacrylic acid copolymers, and combinations of two or more thereof.

5. The integrated back-sheet of claim 1, wherein, the polyolefins are selected from the group consisting of homopolymers of an olefin and copolymers of two or more distinct olefins.

6. The integrated back-sheet of claim 5, wherein, the polyolefins are selected from the group consisting of linear or branched poly-α-olefins and cyclic polyolefins.

7. The integrated back-sheet of claim 6, wherein, the polyolefins are selected from the group consisting of high density polyethylenes (HDPE), polypropylenes (PP), low density polyethylenes (LDPE), linear low density polyethylenes (LLDPE), and combinations of two or more thereof.

8. The integrated back-sheet of claim 1, wherein, the polymeric substrate is comprised of one or more polymeric materials selected from the group consisting of polyester, fluoropolymer, polycarbonate, polypropylene, polyethylene, cyclic polyolefin, acrylic, cellulose acetate, acrylate polymer, polystyrene, styrene-acrylate copolymers, acrylonitrile-styrene copolymers, poly(ethylene naphthalate), polyethersulfone, polysulfone, polyamide, epoxy resin, glass fiber reinforced polymer, carbon fiber reinforced polymer, vinyl chloride polymers, polyvinylidene chloride, vinylidene chloride copolymers, and combinations of two or more thereof.

9. The integrated back-sheet of claim 8, wherein, the polymeric substrate is comprised of one or more polymeric materials selected from the group consisting of polyesters, fluoropolymers, and combinations of two or more thereof.

10. The integrated back-sheet of claim 1, wherein, the polymeric substrate is in form of a mono-layer sheet or film or in the form of a multi-layer sheet or film.

11. The integrated back-sheet of claim 1, wherein, the electrically conductive metal circuits are formed from a metal foil.

12. The integrated back-sheet of claim 11, wherein, the electrically conductive metal circuits are formed of a foil of aluminum, tin, copper, nickel, silver, gold, tin coated copper, silver coated copper, gold coated copper, steel, invar, or alloys of two or more thereof.

13. The integrated back-sheet of claim 12, wherein, the electrically conductive metal circuits are formed of a copper foil.

14. A back-contact solar cell module, comprising:
a) integrated back-sheet of claim 1;
b) an insulating layer adhered to the electrically conductive metal circuits of the integrated back-sheet, wherein the insulating layer comprises a plurality of openings that are filled with electrically conductive material;
c) a plurality of back-contact solar cells having a light receiving side and an opposite back side, wherein, the back contact solar cells each have a plurality of electrical contacts on their back side in a pattern corresponding to the pattern of openings in the insulating layer that are filled with electrically conductive material, and wherein, the back side of the plurality of back-contact solar cells are adhered to the insulating layer such that the electrical contacts on the back side of the solar cells are in electrical contact with the electrically conductive metal circuit through the electrically conductive material in the openings in the insulating layer;
d) a front encapsulant layer adhered to the front side of the back-contact solar cells; and
e) a transparent front-sheet adhered to the front encapsulant layer.
